(19) United States
(12) Patent Application Publication
(10) Pub. No.: US 2007/0018673 A1
(43) Pub. Date: Jan. 25, 2007

(54) Electronic component testing apparatus

(75) Inventor: Chih-Hung Hsieh, Hsin-Chu City (TW)

Correspondence Address: Genus Law Group PLLC;Raymond J. Ho; David B. Dort, Box 26219, Crystal City Station, Arlington, VA, 22215, US

(73) Assignee: KING YUAN ELECTRONICS CO., LTD.

(21) Appl. No.: 11/233,589

(22) Filed: Sep. 22, 2005

(30) Foreign Application Priority Data
Jul. 22, 2005 (TW) 94125029

(51) Int. Cl. G01R 31/26

(52) U.S. Cl. 324/765

(57) ABSTRACT

The present invention discloses an electronic testing apparatus, which includes multiple test areas, each area possesses respective pick and place module. The apparatus includes multiple shuttles located between the test area and input/output trays. Moreover, a further pick and place module is utilized, between the shuttles and the input/output trays, for picking and placing the devices under test or tested device.

### BACKGROUND OF THE INVENTION

1. Field of the Invention

The present invention generally relates to an electronic component test device, and more particularly to an Integrated Circuit (ICs) test device, which includes a plurality of shuttles having individual pick and place module.

2. Description of the Prior Art

During the packaging process, Integrated circuit (ICs) may be damaged or packaging may not be correctly performed. The failures introduced during packaging typically cause 1 percent or more of ICs to fail. Therefore it is necessary to perform the final test, which fully inspection performed on each packaged IC prior to shipment, in order to satisfy customer's requirement.

FIG. 1 shows the vertical plan view of conventional test apparatus (handler 100). The handler 100 is a piece of equipment that “handles” the ICs and makes connections to an automatic tester (not shown) via connecting cable. The handler can be divided into two zones, the input/output zone is located in the front area of the handler and the test zone is located in the rear area of the handler. There are several input trays 104 and several output trays 105 stacking arrangement in the input/output zone of the handler. The input trays are used to store the ICs, and the output trays are used to grade the tested ICs according to Binning process, which is a process of sorting parts based on some measured performance parameter such as speed of operation or other criteria.

As shown in FIG. 1, the handling of the ICs/tested ICs is fully automated from the input trays 104 to the output trays 105 by using a fast pick and place module 108 based on XY mechanism with linear motors on magnetic suspension technology. The pick and place module 108 can take any positions of the input/output zone by slipping through x-rail 109 and y-rail 108. The pick and place module 108 picks one IC from input tray 104, putting it in the front depression 115a of the shuttle 114, then moving the shuttle 114 from the input/output zone of the handler 100 to the test zone by the way of track 116.

The other pick and place module 112 located in the test zone picks another tested IC (which had completed the final test) from test area 118 by slipping through y-rail 113 and x-rail 111, and then putting it in the rear depression 115b of the shuttle 114, picking the IC that had previously stored in the front depression 115a of the shuttle 114, putting it in the socket 119 of one test area 118, and proceeding to undergo the final test.

While the final test is undergoing, the pick and place module 108 picks the tested IC which had previously stored in the rear depression 115b of the shuttle 114 by way of the track 116, sorting it by grade then putting in the output tray 105.

Although the conventional handler 100 shown in FIG. 1 has multiple test area 118 (six in the FIG. 1), it has only one shuttle 114 and only one pick and place module 112 can pick the IC to undergo the final test. Accordingly, it is usually more than one tested IC in the test area waiting to be picked to the shuttle 114, but it can be picked until the shuttle 114 is back to the test zone from the input/output zone. In the meantime, the IC that had stored in the front depression 115a also cannot be picked into the test area, that is to say, wasting too much time on wait, and consequently tact time of conventional handler is too long, the tact time is the time needed to manufacture/test one unit of a product, measured as the elapsed time between the completion of one unit and the completion of the next. The long tact time cause the yield decreases significantly. Moreover, if the test time of the IC is shorter, then the time during wait will get longer. For example, if the time need to pick and place is 5 seconds, but the time need to complete test one IC is less than 30 seconds such as 10-15 seconds, then the time of stay in test area will become 10 seconds or longer.

The modern semiconductor production test equipment is increasingly complex to design, build and maintain. In order to decreasing the cost and increasing the yield, it is necessary to make full use of the handler 100 and to avoid idle and to increase the quantity of test per unit time, a need has arisen to propose an apparatus that allows for decreasing the tact time and increasing the yield.

### SUMMARY OF THE INVENTION

In view of the foregoing, it is an object of the present invention to provide a test apparatus for decreasing the probability of tested component stayed in the test area when the final test has finished, and therefore increasing the yield.

In a preferred embodiment, the present invention provides an electronic component testing apparatus, which includes multiple test area and each test area includes individual pick and place module. Furthermore, multiple shuttles are provided, which is moved between the test zone and the input/output zone. In addition, one pick and place module locating in the input/output zone is provided for conveying the ICs or the tested ICs.

### BRIEF DESCRIPTION OF THE DRAWINGS

FIG. 1 shows the vertical plan view of conventional ICs test apparatus (handler).

FIG. 2 shows the vertical plan view of ICs test apparatus according to one embodiment of the present invention.

FIG. 3A and FIG. 3B illustrate two diagrams of IC/tested IC being picked/placed by the I/O pick and place module of present invention.

FIG. 4 show a front side view taken on the front side of the handler according to one embodiment of the present invention.

FIG. 5 show a rear side view taken on the rear side of the handler according to one embodiment of the present invention.

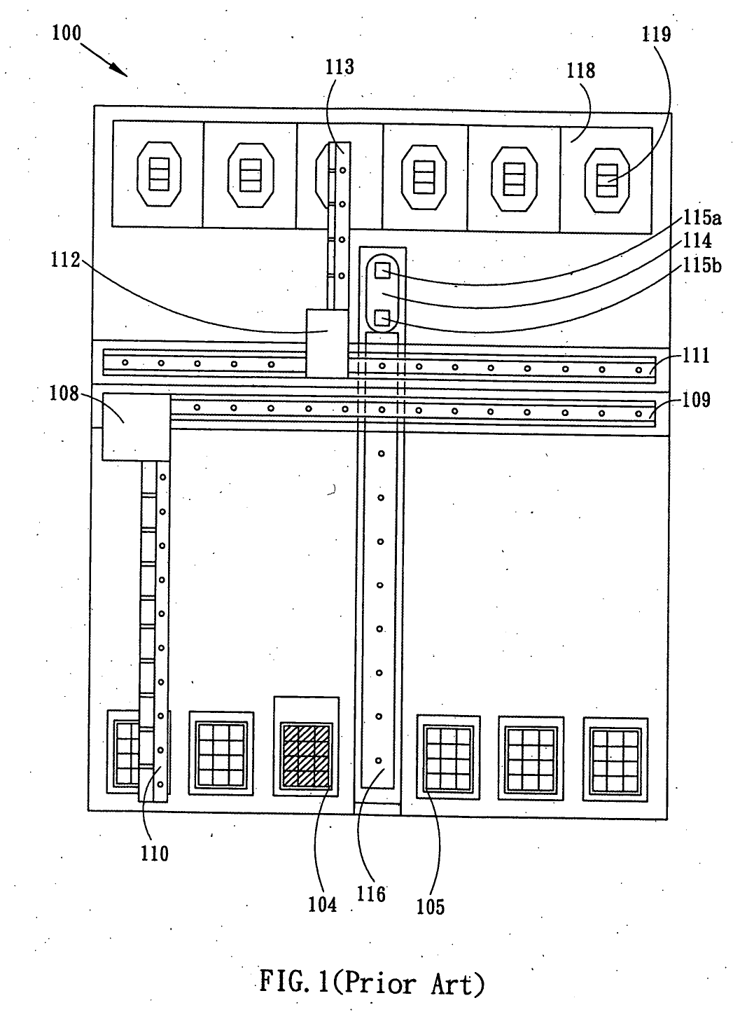

### DESCRIPTION OF THE PREFERRED EMBODIMENT

The detailed description of the present invention will be discussed in the following embodiment, which is not intended to limit the scope of the present invention, but can be adapted for other applications. While drawings are illustrated in details, it is appreciated that the quantity of the disclosed components may be greater or less than that disclosed, except expressly restricting the amount of the components.

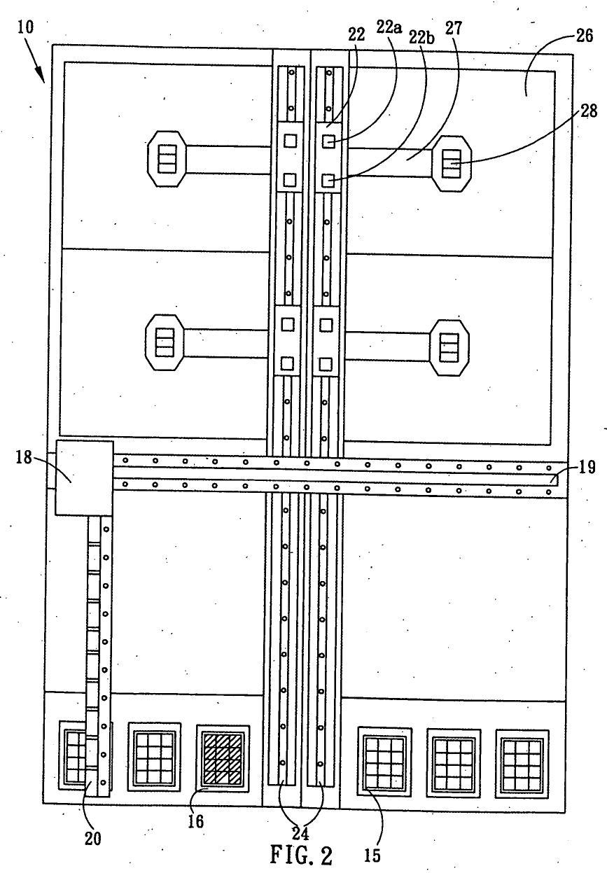

FIG. 2 shows the vertical plan view of ICs test apparatus according to one embodiment of the present invention. Pluralities of input trays 16 for storing the ICs are stacking arrangements in the input/output zone of the handler 10. Each of the input trays 16 with a plurality of IC aligned thereon. Similar to input trays 16, there is also at least one output tray 15 located within the input/output zone for storing the tested IC. The tested ICs are graded to output trays 15 according to measured parameter. The number of input/output trays 16/15 and their location can be adjusted according to actual requirement.

Several test areas 26 are provided in the test zone of the handler 10, it has four aligning in two columns in this embodiment. Either of the number of test area 26 or the way of aligned could be changed in other embodiment according to present invention. A socket 28 is provided in each test area 26, it is used to connect the IC and the automatic test system (not shown) for undergoing a final test. In addition, a test-pick and place module 27 is located in each test area 26 for picking the tested IC from the socket 28, or placing the IC in the socket 26. Furthermore, the test-pick and place module 27 having contact mechanism is employed for pressing and retaining the IC even providing heat to the IC while the final test is undergoing. In this embodiment, the socket 28 is connected to real system such as motherboard or CD-ROM drive. However, the socket can also be connected to non-real system, for such case, the socket 28 will be connected to the test head of non-real system.

As shown in the FIG. 2, the handler 10 has multiple (four in this embodiment) shuttles 22, and the shuttle has front depression 22a and rear depression 22b on it, which is used to store the IC and the tested IC respectively. The shuttles 22 carry the IC from the input/output zone to the test zone, or carry the tested IC from the test zone to the input/output zone by slipping through several tracks 24 (two in this embodiment), furthermore, the track 24 is capable of carrying more than one shuttle on it in the meantime.

A I/O-pick and place module 18 locating in the input/output zone of the handler 10 is used for picking one piece of IC from the input tray, and then placing it in the front depression 22a of the shuttle 22; or picking one piece of tested IC from the rear depression 22b of the shuttle 22, and then placing it in the different graded output trays according to the test result.

The sequence of whole testing process is becoming simpler, clearer and sooner than before, now describing as following: The I/O-pick and place module 18 picks one piece of IC form the input tray 16, and then placing it in the front depression 22a of the shuttle 22. After that, the shuttle 22 moves to the test zone by way of track 24. Then the test-pick and place module 27 picks this IC and placing it into socket 28 to undergo the final test. According the present invention, because the handler 10 has multiple shuttles and multiple tracks, so that the shuttles 22 are capable of moving the IC to the test zone on request immediately, without waiting the shuttles 22 back to input/output zone. It is the same reason the tested ICs can be carried to the input/output zone without waiting the shuttles 22 back to test zone. According to this embodiment of the present invention, it has decreased the waiting time of the tested IC significantly as well as makes full use of the test apparatus, consequently increasing the yield.

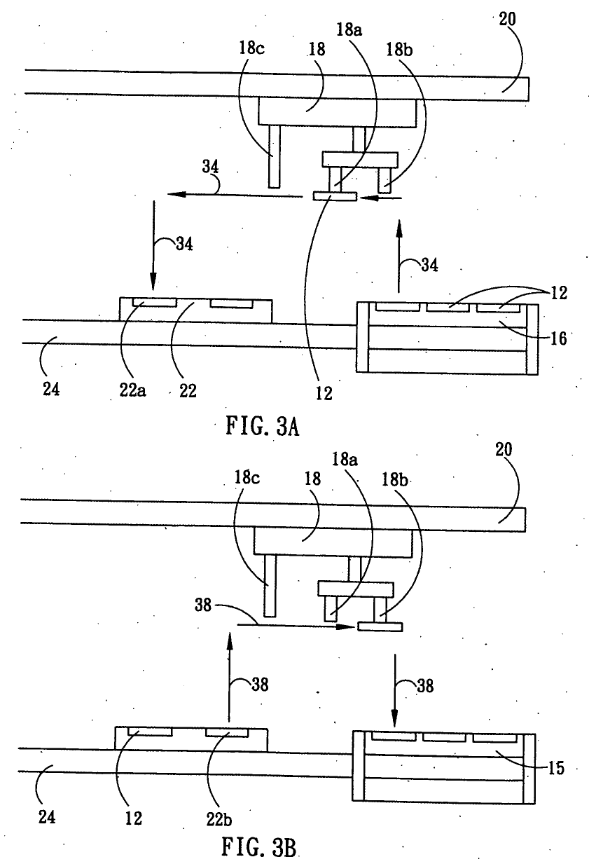

FIG. 3A and FIG. 3B illustrate two diagrams of IC/tested IC being picked/placed by the pick and place module 27 of present invention. The I/O-pick and place module 18 locating in the input/output zone includes input suction head 18a, output suction head 18b, and tray picker 18c. FIG. 3A shows the image of sucking the IC 12. The input suction head 18a aims at the input tray 16 then sucking the IC 12 form it, following the direction 34 then putting the IC 12 in the front depression 22a of the shuttle 22. Moreover, the input suction head 18a is capable of reversing the IC 12 if there is a need before it is put into the front depression 22a. FIG. 3B shows the image of placing the IC 12. The output suction head 18b aims at the rear depression 22b then sucking the IC 12 form it, following the direction 38 then putting the IC 12 in the output tray 15. Moreover, the output suction head 18b is capable of reversing the IC 12 if there is a need before it is put into the rear depression 22b.

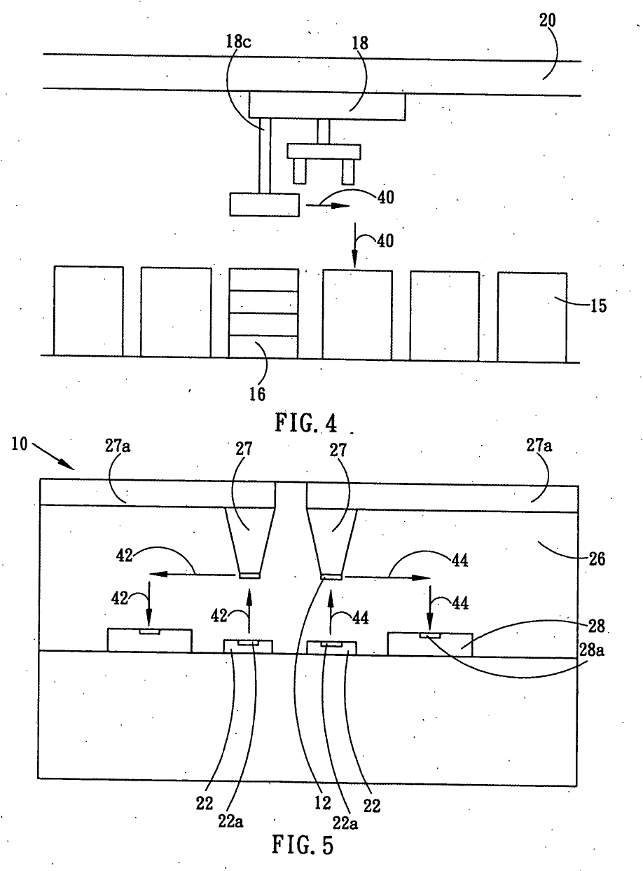

FIG. 4 shows a side view taken on the front side of the handler 10. When all of the ICs in the top of a stack of input trays 16 have picked and becoming empty, the empty input tray 16 will be moved away by the tray picker 18c following the direction of 40, or moving to the output zone as the output tray 15. The location of the empty input tray 16 will be replaced by raising the input tray under it while the empty input tray is picking by tray picker 18c. Again, the ICs could be picked from the input tray 16 which had risen previously.

FIG. 5 shows a side view taken on the rear side of the handler 10. After the IC 12 has moved to one test area 26 of the test zone, the test-pick and place module 27 picks the IC 12 and placing it into the socket 28 following the direction of 42, and then proceeding to undergo the final test. The contact mechanism of the test-pick and place module 27 will press and retain the IC 12 until the final test is finished. After the final test has done, the test-pick and place module 27 will pick the tested IC 12 from the socket 28, and then putting it into the rear depression 22b following in the opposite direction of 42. As show in the right section of FIG. 5A, similar to the left section of FIG. 5A, the IC 12 follow in the direction of 44 to undergo the final test, and the IC 12 follow in the opposite direction of 44 to store the tested IC in the shuttle 22 when the final test has finished.

Although specific embodiments have been illustrated and described, it will be appreciated by those skilled in the art that various modifications may be made without departing from the scope of the present invention, which is intended to be limited solely by the appended claims.

1. An electronic component test apparatus, comprising:
at least one input trays for storing the electronic component prior to proceeding a test;
at least one output trays for storing the tested electronic component;
a plurality of test areas for testing the electronic component;
a plurality of shuttles moving between said test area and said input trays or said output trays for carrying the electronic component or tested electronic component; and
a plurality of tracks for moving a plurality of said shuttles at the same time wherein each of said a plurality of tracks is capable of carrying more than one said shuttle on it on the meantime; and
a I/O-pick and place module for picking or placing the electronic component between said input/output trays and said shuttles.

2. The electronic component test apparatus as set forth in claim 1, wherein said test area further comprises a socket for setting the electronic component prior to undergo the test.

3. The electronic component test apparatus as set forth in claim 2, wherein said test area further comprising a test-pick and place module for picking or placing the tested electronic component between said socket and said shuttle, and pressing and retaining the electronic component until the test has finished.

4. The electronic component test apparatus as set forth in claim 1, wherein said shuttles include a front depression and a rear depression for storing the electronic component and the tested electronic component respectively.

5. (canceled)

6. The electronic component test apparatus as set forth in claim 1, wherein said I/O-pick and place module includes an input suction head for sucking the electronic component and reversing the electronic component according to requirement.

7. The electronic component test apparatus as set forth in claim 1, wherein said test-pick and place module includes an output suction head for sucking the tested electronic component and reversing the tested electronic component according to requirement.

8. The electronic component test apparatus as set forth in claim 1, wherein said I/O-pick and place module includes a tray picker for picking said input tray or said output tray.

9. The electronic component test apparatus as set forth in claim 1, further comprising a Y-rail for moving said I/O-pick and place module in Y-direction.

10. The electronic component test apparatus as set forth in claim 9, further comprising a X-rail for moving said I/O-pick and place module in X-direction.

11. An electronic component test apparatus, comprising:
at least one input trays for storing the electronic component prior to proceeding a test;
at least one output trays for storing the tested electronic component;
a plurality of test areas for testing the electronic component;
a plurality of test-pick and place module for picking or placing the tested electronic component or the electronic component wherein each of said a plurality of test areas has one said test-pick and place module, and said test-pick and place module have contact mechanism employed for pressing said electronic component and provide heat to said electronic component in testing time;
a plurality of shuttles moving between said test area and said input trays or said output trays for carrying the electronic component or tested electronic component; and
a I/O-pick and place module for picking or placing the electronic component between said input/output trays and said shuttles.

12. The electronic component test apparatus as set forth in claim 11, wherein said test area further comprises a socket for setting the electronic component prior to undergo the test.

13. The electronic component test apparatus as set forth in claim 11, wherein said shuttles include a front depression and a rear depression for storing the electronic component and the tested electronic component respectively.

14. The electronic component test apparatus as set forth in claim 11, further comprising a plurality of tracks for moving a plurality of said shuttles at the same time.

15. The electronic component test apparatus as set forth in claim 11, wherein said I/O-pick and place module includes an input suction head for sucking the electronic component and reversing the electronic component according to requirement.

16. The electronic component test apparatus as set forth in claim 11, wherein said test-pick and place module includes an output suction head for sucking the tested electronic component and reversing the tested electronic component according to requirement.

17. The electronic component test apparatus as set forth in claim 11, wherein said I/O-pick and place module includes a tray picker for picking said input tray or said output tray.

18. The electronic component test apparatus as set forth in claim 11, further comprising a Y-rail for moving said I/O-pick and place module in Y-direction.

19. The electronic component test apparatus as set forth in claim 11, further comprising a X-rail for moving said I/O-pick and place module in X-direction.
